(19) United States
(12) Patent Application Publication
(10) Pub. No.: US 2018/0284179 A1
(43) Pub. Date: Oct. 4, 2018

(54) TRANSMISSION APPARATUS AND CONNECTION MONITORING METHOD

(71) Applicant: FUJITSU LIMITED, Kawasaki-shi (JP)

(72) Inventors: Masato Hashizume, Souraku (JP); Masato KOBAYASHI, Oyama (JP); Takao YASUI, Iwakura (JP)

(73) Assignee: FUJITSU LIMITED, Kawasaki-shi (JP)

(21) Appl. No.: 15/939,638

(22) Filed: Mar. 29, 2018

(30) Foreign Application Priority Data
Apr. 3, 2017 (JP) 2017-073940

(51) Int. Cl. G01R 31/04

(52) U.S. Cl. CPC G01R 31/046; H01R 12/73

(57) ABSTRACT

A transmission apparatus includes a first circuit, a second circuit, and a connector that couples the first circuit and the second circuit to each other, the first circuit includes a signal generation circuit that outputs an alternate current signal of a predetermined power at a frequency from a carrier frequency to three times the carrier frequency, and one of the first circuit and the second circuit includes a determination circuit that evaluates a fit state at the connector by determining whether the first circuit and the second circuit are fitted to each other via the connector based on the predetermined power and a power of the alternate current signal received by the determination circuit via the connector.

### CROSS-REFERENCE TO RELATED APPLICATION

This application is based upon and claims the benefit of priority of the prior Japanese Patent Application No. 2017-73940, filed on Apr. 3, 2017, the entire contents of which are incorporated herein by reference.

### FIELD

The embodiments discussed herein are related to a transmission apparatus and a connection monitoring method.

### BACKGROUND

There is used a mechanism for monitoring whether boards or cards that are to be coupled to each other with a connector are fitted in the connector. In a mother-daughter type apparatus in which a motherboard and a daughterboard are coupled to each other with a multipin connector, signal continuity is hindered when the daughterboard is inserted in an improper manner such as slanted insertion. To detect a poor fit or loose insertion, a test to check continuity of a DC signal is conducted by, typically, passing a DC signal or by applying voltages of logic signals of two values alternately.

Meanwhile, with the size reduction and spacing-saving trends of devices, requirements for connection reliability are becoming higher and higher, and to meet the requirements, multipoint contact connector terminals are used.

With the increase in signal rates in recent years, an influence by signal degradation of signals in a high-frequency band has begun surfacing at the connector connection part. A conventional connector connection monitoring system that conducts a test using a DC signal is unable to handle continuity tests for high-frequency signals.

A multicontact connector pin achieves high connection reliability by having a plurality of (two, for example) contact points in one pin. When multipoint contact is employed, a current flows even if any of the contact points is not in contact. It is therefore difficult for a conventional connection monitoring system that uses a DC signal to detect a poor connection in an apparatus using high-frequency signals.

Related techniques are disclosed in, for example, Japanese Laid-open Patent Publication Nos. 2008-203115 and 2012-8028.

### SUMMARY

According to an aspect of the invention, a transmission apparatus includes a first circuit, a second circuit, and a connector that couples the first circuit and the second circuit to each other. The first circuit has a signal generation circuit that outputs an alternate current signal of a predetermined power at a frequency from a carrier frequency to three times the carrier frequency. One of the first circuit and the second circuit has a determination circuit that evaluates a fit state at the connector by determining whether the first circuit and the second circuit are fitted to each other via the connector based on the predetermined power and a power of the alternate current signal received by the determination circuit via the connector.

The object and advantages of the invention will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIGS. 1A and 1B are diagrams illustrating a poor connection caused in inter-board connection to which a transmission apparatus of an embodiment is applied;

FIGS. 2A to 2C are diagrams illustrating signal degradation caused when a multipoint contact terminal is used;

FIG. 3 is a diagram illustrating degradation in electrical signals in a high-frequency band;

FIG. 4 is a diagram illustrating the basic configuration of a transmission apparatus of a first embodiment;

FIGS. 5A and 5B are diagrams illustrating an example of transmission loss information on a printed circuit board;

FIG. 6 is a flowchart of a connection monitoring method of the embodiment;

FIG. 7A is a diagram illustrating an application example of a transmission apparatus;

FIG. 7B is a diagram illustrating an application example of a transmission apparatus;

FIG. 8 is a diagram illustrating an example configuration of a sine wave generation circuit used in FIGS. 7A and 7B;

FIG. 9 is a diagram illustrating an application example of a transmission apparatus;

FIG. 10 is a diagram illustrating an application example of a transmission apparatus;

FIG. 11 is a diagram illustrating yet another application example of a transmission apparatus;

FIG. 12 is a diagram illustrating yet another application example of a transmission apparatus;

FIG. 13 is a diagram illustrating yet another application example of a transmission apparatus;

FIG. 14 is a diagram illustrating an example of how a connector fit monitor line is laid;

FIG. 15 is a diagram illustrating another example of how the connector fit monitor line is laid; and

FIG. 16 is a diagram illustrating a modification of the transmission apparatus.

### DESCRIPTION OF EMBODIMENTS

Before a transmission apparatus and a connection monitoring method of an embodiment are described, a more detailed description is given of technical problems in connector connection found by the inventors and basic concepts for solving the problems.

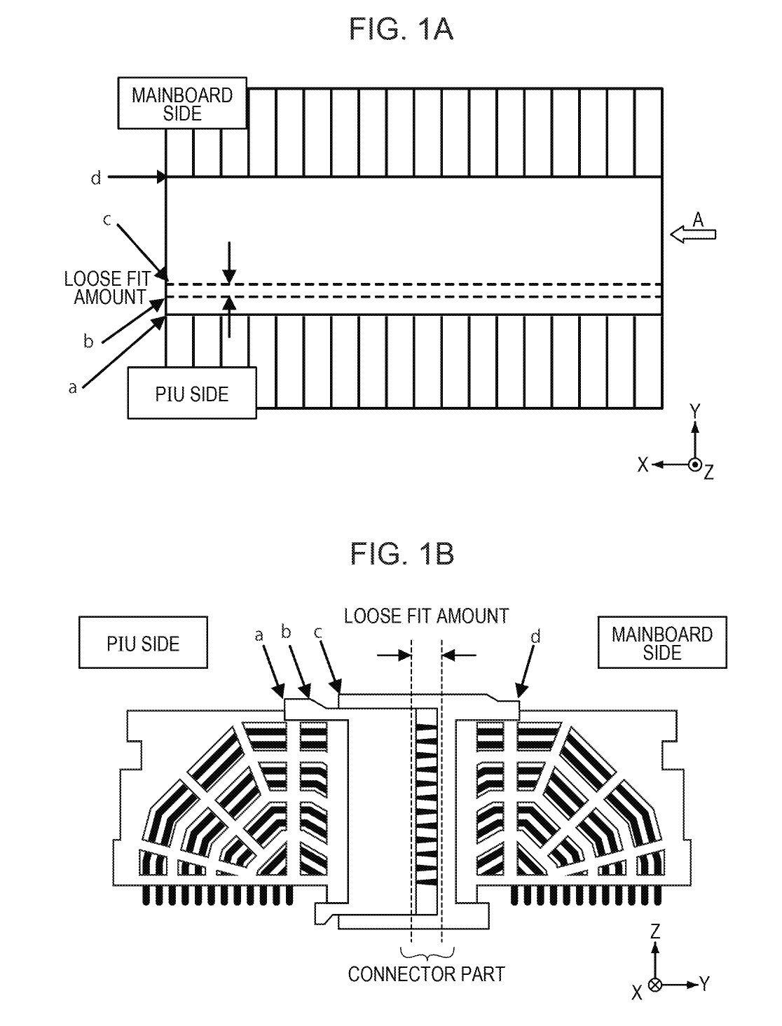

FIGS. 1A and 1B are diagrams illustrating a poor connection caused in the inter-board connection. The transmission apparatus and the connection monitoring method of the embodiment are applicable to general electrical signal transmissions but are particularly useful when high-speed transmission or a multicontact connector is used.

FIG. 1A is a top view of an apparatus in which a mainboard and a plug-in unit (PIU) are coupled to each other via a connector, and FIG. 1B is a side view of the apparatus seen in the direction of arrow A. The Y direction is the direction in which the PIU is fitted, the Z direction is the height direction of the mainboard, and the X direction is the direction orthogonal to the Y direction and the Z direction. In a connector part, a plurality of pins are arranged in the Z direction. When the PIU is inserted in the mainboard properly, all the pins are coupled to their corresponding terminals, achieving electrical connection. When the PIU is not completely fitted in the mainboard, by being obliquely inserted in the mainboard for example, a loose fit occurs in the connector, degrading signals at the incomplete connection area.

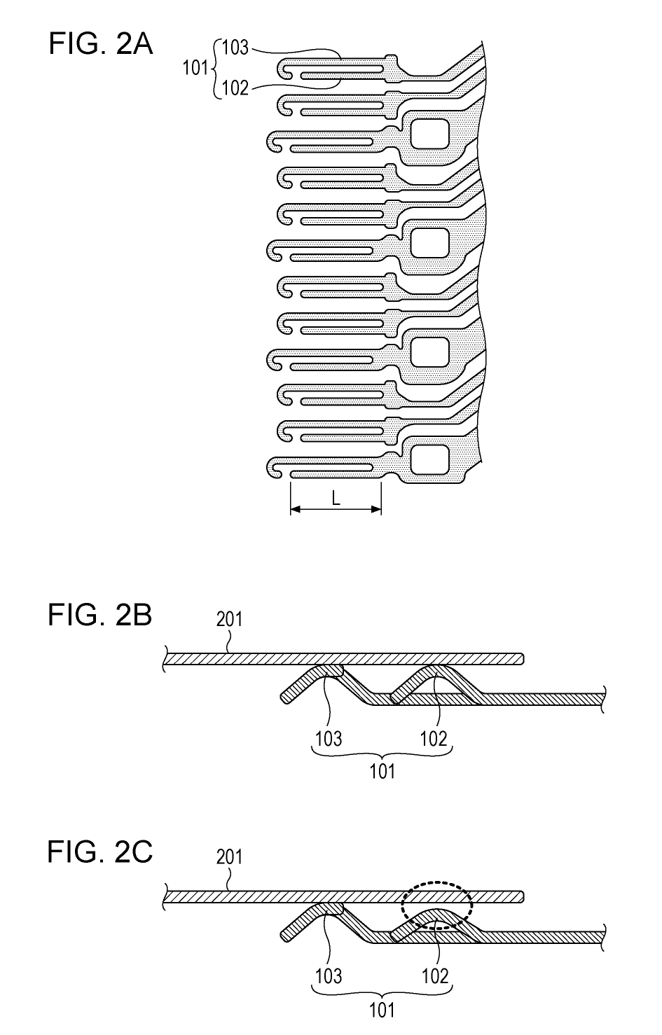

FIGS. 2A to 2C are diagrams illustrating signal degradation due to a poor connection of multicontact terminals. In FIG. 2A, a plurality of connector pins 101 are arranged in a predetermined direction. If applied to the configuration of FIGS. 1A and 1B, the connector pins 101 are arranged in the Z direction. Each of the connector pins 101 has a first terminal 102 and a second terminal 103. To assure the connection reliability of the connector pin 101, the first terminal 102 and the second terminal 103 have different lengths and different shapes. The first terminal 102 may be called a short terminal, and the second terminal 103 may be called a long terminal.

FIG. 2B illustrates the connector pin 101 properly coupled, and FIG. 2C illustrates the connector pin 101 one of whose terminals is experiencing a poor contact. While the short terminal and the long terminal are both in contact with a corresponding connection terminal 201 in FIG. 2B, the short terminal is loose (out of contact) in FIG. 2C. Since the connector pin 101 permits electrical continuity even with one of the terminals being loose, the connection abnormality in FIG. 2C is undetectable by a conventional monitor line.

When the short terminal (namely the first terminal 102) is loose as illustrated in FIG. 2C, the short terminal acts as a stub. A stub is a distributed constant line coupled in parallel with a transmission line in a high frequency circuit. When a connector joint part has a stub, signal degradation becomes apparent due to reflection in a frequency band of L≈λ/4 where L is the length of the stub and λ is the wavelength used. This is because a signal reflected by the stub has a reversed phase from the phase of an original signal and cancels out the original signal.

When the stub length L within the connector is 4 mm, the effect of the stub reflection is more prominent when the transmission rate is 37.4 Gbps (wavelength λ=16 mm, 18.7 GHz) than when the transmission rate is 25 Gbps (wavelength λ=24 mm, 12.5 GHz).

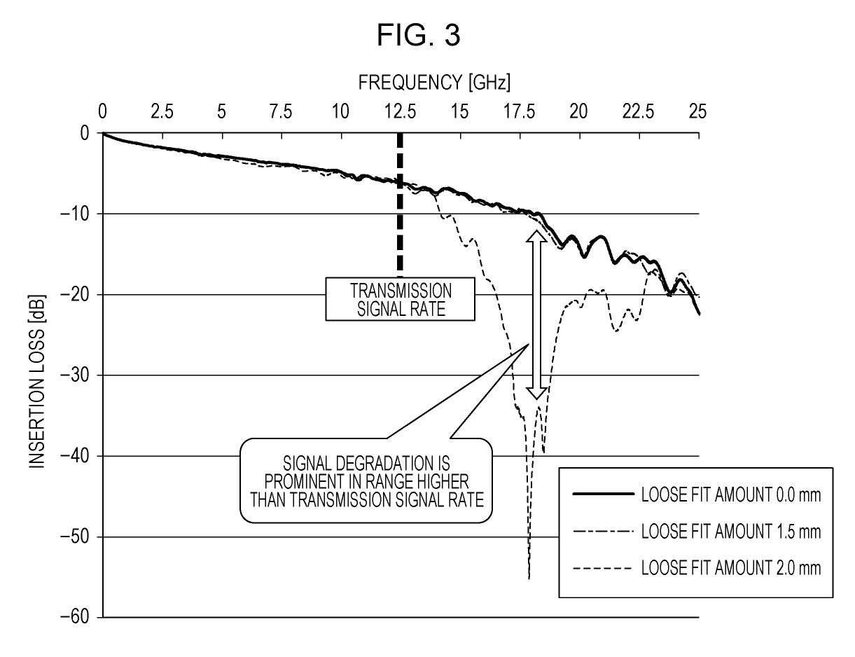

FIG. 3 is a diagram illustrating electrical signal degradation in a high-frequency band. Using the connector pin 101 of FIG. 2A (whose short terminal is 4 mm long), insertion loss is plotted as a function of a frequency for the loose fit amounts of 0.0 mm, 1.5 mm, and 2.0 mm at the connector part. There is no significant change in transmission characteristics (signal degradation) in a frequency band up to 12.5 GHz, but when the loose fit amount is 2.0 mm, the transmission characteristics drastically degrade in a high-frequency band over 12.5 GHz.

With user interfaces becoming faster, the transmission rate of electrical signals on a printed circuit board (PCB) is increasing. With high electrical signal rates, a loose fit which may not affect signal continuity may cause signal degradation, adversely affecting services. A conventional method which monitors DC voltages by laying a monitor line on the connector is unable to detect a loose fit which is not causing line disconnection.

Meanwhile, a high-speed electrical signal transmitted on the PCB contains a harmonic component besides the carrier frequency, and the harmonic component also affects data transmission. The inventors have reached a finding that even if it is difficult to detect a poor fit by monitoring the carrier frequency itself, it is possible to detect a poor fit of a connector by monitoring signal degradation that appears in a harmonic component as illustrated in FIG. 3.

For example, connector's fit abnormality is undetectable when a high-speed electrical signal itself is monitored in the 12.5 GHz band. However, use of a frequency band that affects transmission of a high-speed electrical signal (in the example of FIG. 3, the domain exceeding 12.5 GHz) makes signal degradation prominent according to the loose fit amount. Thus, whether signal degradation has occurred due to a connector's loose fit is tested using the band exceeding the signal frequency. For example, a poor fit permitting signal continuity is detected by connection monitoring that uses an alternate current (AC) signal in a domain containing the second harmonic and the third harmonic of a transmission signal.

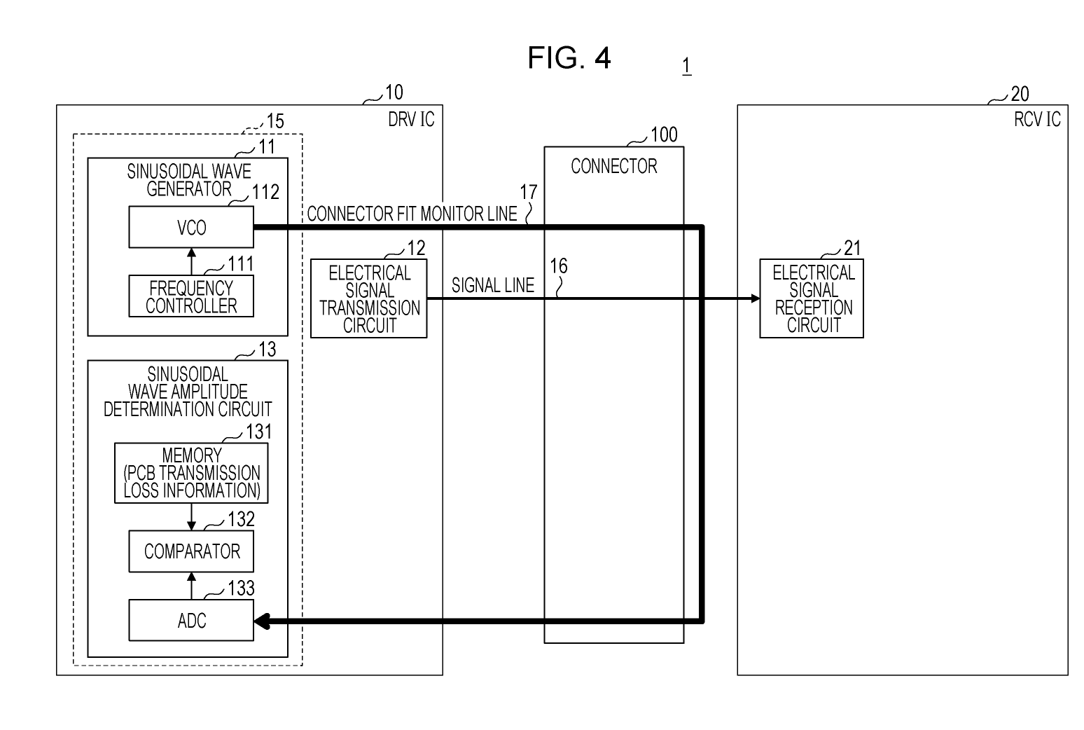

FIG. 4 is a diagram illustrating the basic configuration of a transmission apparatus 1 according to a first embodiment. The transmission apparatus 1 has a motherboard 10 and a daughterboard 20 coupled to each other with a connector 100. The motherboard 10 is an example of the first circuit, and the daughterboard 20 is an example of the second circuit. For example, the connector 100 includes a receptacle provided to the motherboard 10 and a plug provided to the daughterboard 20.

The motherboard 10 includes a driver chip (denoted as “DRV IC” in FIG. 4) and has an electrical signal transmission circuit 12. The daughterboard 20 includes a receiver chip (denoted as “RCV IC” in FIG. 4) and has an electrical signal reception circuit 21. The electrical signal transmission circuit 12 and the electrical signal reception circuit 21 are coupled to each other with a signal line 16 including connection terminals of the connector 100, and electrical signals such as user data are transmitted and received via the signal line 16. Since communications between boards are typically bidirectional, another electrical signal reception circuit may be provided in the motherboard 10, and another electrical signal transmission circuit may be provided in the daughterboard 20.

The transmission apparatus 1 has a connection monitor 15 that monitors the inter-board fit state at the connector 100. The connection monitor 15 has a sine wave generation circuit 11, a sine wave amplitude determination circuit 13, and a connector fit monitor line 17 that couples the sine wave generation circuit 11 and the sine wave amplitude determination circuit 13 to each other.

The sine wave generation circuit 11 generates and outputs an AC signal at a frequency higher than the transmission rate at which user data is transmitted via the signal line 16. For example, the sine wave generation circuit 11 generates an AC signal in a range from the carrier frequency of user data to the third harmonic of the carrier frequency of user data. The sine wave generation circuit 11 may have any configuration as a signal generation circuit as long as the sine wave generation circuit 11 is able to generate an AC signal at a frequency higher than the carrier frequency of user data. In the example in FIG. 4, the sine wave generation circuit 11 has a frequency controller 111 and a voltage-controlled oscillator (VCO) 112.

Based on the amplitude of a sine wave received through the connector fit monitor line 17, the sine wave amplitude determination circuit 13 detects degradation in the amplitude of the received sine wave. The sine wave received is a wave that has passed through the connector 100, and based on degradation in the amplitude of the received sine wave, the sine wave amplitude determination circuit 13 is able to determine whether there is a poor inter-board fit at the connector 100. For example, when the received sine wave has a transmission loss higher than a predetermined level, the sine wave amplitude determination circuit 13 determines that there is a poor inter-board fit at the connector 100.

The “connector fit monitor line” in this specification and the drawings does not refer to an actual signal line, but is a schematic expression of a propagation path for a sine signal for fit monitoring. For example, an actual monitor signal line forming the connector fit monitor line 17 is such that a signal wire extending from the VCO 112 of the sine wave generation circuit 11 is coupled to one end of the array of the connector pins 101 (see FIGS. 1A and 1B), so that a sine signal is outputted from the connector 100 to the daughterboard 20. The sine signal outputted to the daughterboard 20 is inputted to the other end of the connector pin array via a wire extending along a side wall of the connector 100, outputted to the motherboard side, and inputted to an ADC 133 of the sine wave amplitude determination circuit 13.

The sine wave amplitude determination circuit 13 may employ any configuration to be able to detect degradation in the amplitude of the sine wave received through the connector fit monitor line 17. In the example in FIG. 4, the sine wave amplitude determination circuit 13 has a memory 131, an analog-to-digital converter (ADC) 133, and a comparator 132.

The memory 131 stores PCB transmission loss information which is used as a standard for comparison and determination. A transmission loss is determined by a signal transmission rate (or frequency) and the wire length. The PCB transmission loss information may be stored as a function of a signal transmission rate or in a table format.

The ADC 133 subjects a sine wave received through the connector fit monitor line 17 to digital conversion, and obtains a digital value of the amplitude thereof. The comparator 132 compares an output from the ADC 133 with the PCB transmission loss information in the memory 131. Based on a result outputted from the comparator 132, the sine wave amplitude determination circuit 13 determines whether the connector 100 has a poor fit. For example, if the detected amplitude degradation exceeds the tolerable transmission loss in the memory 131, the sine wave amplitude determination circuit 13 determines that the connector 100 has a poor fit. If determining that the connector 100 has a poor fit or detecting a poor fit for a certain period of time or longer, the sine wave amplitude determination circuit 13 may output a warning.

This configuration enables an appropriate determination of whether there is occurring a poor fit which is allowing continuity through the connector 100 but causing signal degradation.

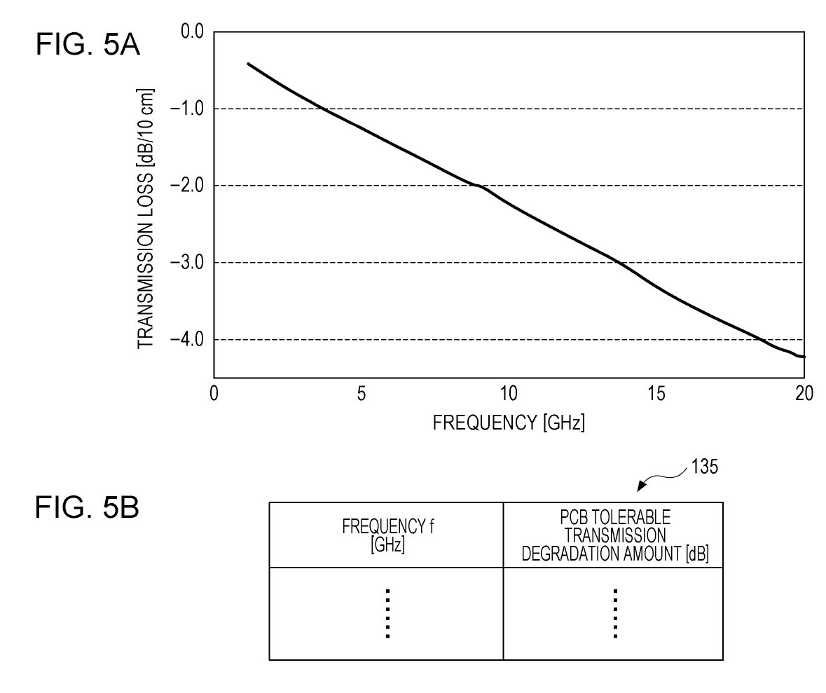

FIGS. 5A and 5B are an example of PCB transmission degradation amount information stored in the memory 131. In FIG. 5A, a transmission loss observed when a low-dielectric PCB is used is plotted as a function of frequency. If the function in FIG. 5A is used, the sine wave amplitude determination circuit 13 determines that transmission degradation through the connector fit monitor line 17 is beyond the tolerable range when the transmission degradation amount calculated by the sine wave amplitude determination circuit 13 is below the line in FIG. 5A at the corresponding transmission frequency.

FIG. 5B is a table 135 depicting the relation between frequency and PCB tolerable transmission degradation amount. The table 135 in FIG. 5B may be stored in the memory 131. If the table 135 is used, the sine wave amplitude determination circuit 13 determines that transmission degradation is within the tolerable range when the calculated amount of sine wave amplitude degradation is equal to or below the tolerable PCB transmission degradation amount for the corresponding frequency.

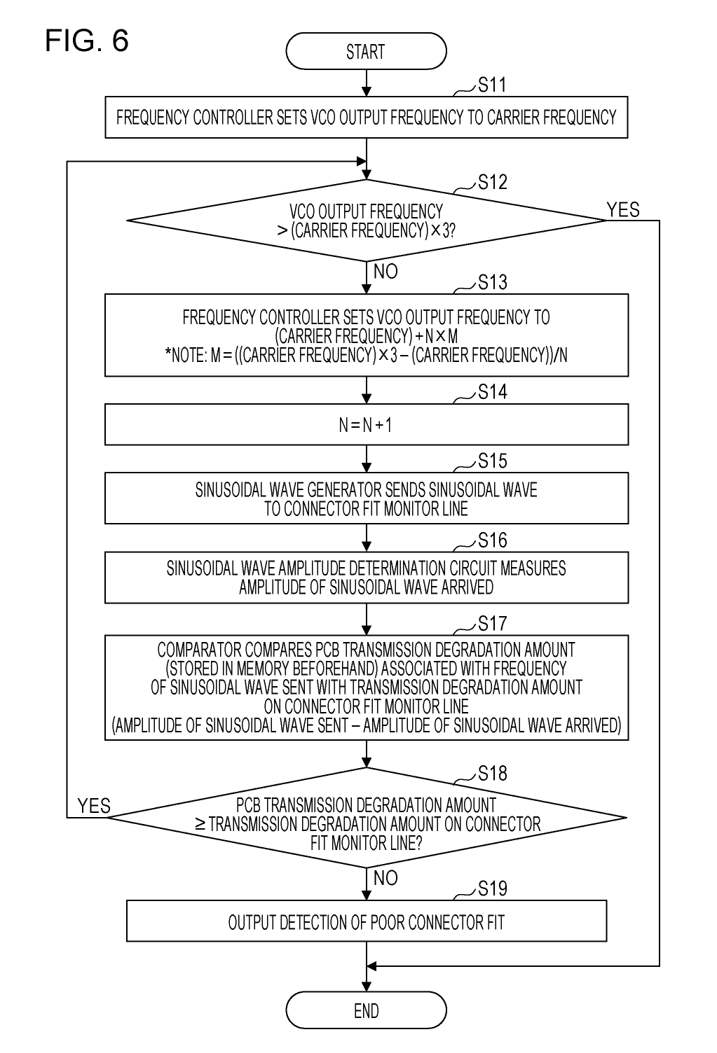

FIG. 6 is a flowchart of the connection monitoring method of the embodiment. The connection monitoring process is executed by the connection monitor 15 in FIG. 4. The connection monitoring process monitors signal degradation state while increasing the VCO oscillating frequency gradually up to the third harmonic of the carrier frequency.

First, the frequency controller 111 sets the output frequency of the VCO 112 to the carrier frequency (S11). The carrier frequency is the frequency of a carrier wave used to transmit an electrical signal through the signal line 16. Next, the frequency controller 111 determines whether the output frequency of the VCO 112 is higher than three times the carrier frequency (S12). Since the output frequency is set to the carrier frequency at the beginning of the connection monitoring process, the result of the determination is negative (NO in S12). In this case, the frequency controller 111 sets the output frequency of the VCO 112 to (carrier frequency)+N×M (S13). M is the step size for changing the frequency, and is expressed as M=[(carrier frequency)×3-(carrier frequency)]/N, where N is the number of a control loop. The initial value for N is N=0. In Step S14, the value of N is incremented by one (N=N+1).

The sine wave generation circuit 11 generates a sine wave at an output frequency determined by the value of N thus incremented and the value of M, and outputs the sine wave to the connector fit monitor line 17 (S15). The sine wave amplitude determination circuit 13 receives the sine wave that has passed through the connector 100, and measures the amplitude thereof (S16). The sine wave amplitude determination circuit 13 calculates the amplitude degradation amount for the received sine wave. For example, the sine wave amplitude determination circuit 13 calculates the difference between the amplitude of the sine wave transmitted and the amplitude of the sine wave received as the transmission degradation amount on the connector fit monitor line 17. The transmission degradation amount thus calculated is compared with the PCB tolerable transmission degradation amount stored in the memory 131 beforehand (S17). Then it is determined whether or not the amplification degradation amount for the sine wave, or in other words, the transmission degradation amount on the connector fit monitor line 17 is equal to or below the PCB tolerable transmission degradation amount (S18). If the transmission degradation amount is equal to or below the PCB tolerable transmission degradation amount (YES in S18), the process returns to Step S12 to repeat S12 to S18 until the VCO output frequency exceeds three times the carrier frequency. Once the VCO output frequency exceeds three times the carrier frequency (YES in S12), the frequency domain for determining signal degradation is exceeded, so the processing ends.

If the transmission degradation amount on the connector fit monitor line 17 is above the PCB tolerable transmission degradation amount in S18 (NO in S18), the sine wave amplitude determination circuit 13 outputs a detection result indicative of a poor fit at the connector (S19). A notification of the detection result indicative of a poor fit at the connector is given to, for example, a maintainer of the transmission apparatus 1.

This connection monitoring method enables detection of a poor fit which is being caused by a partial out-of-contact state but is not hindering signal continuity.

### APPLICATION EXAMPLE 1

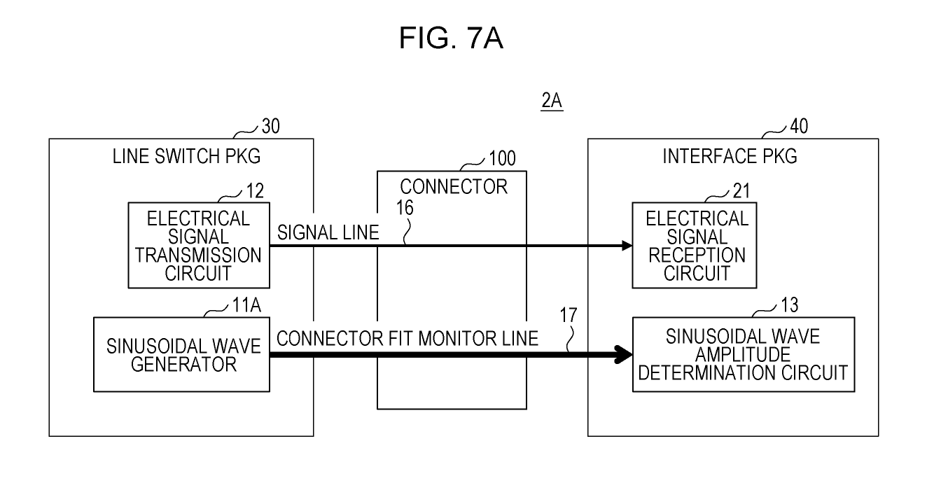

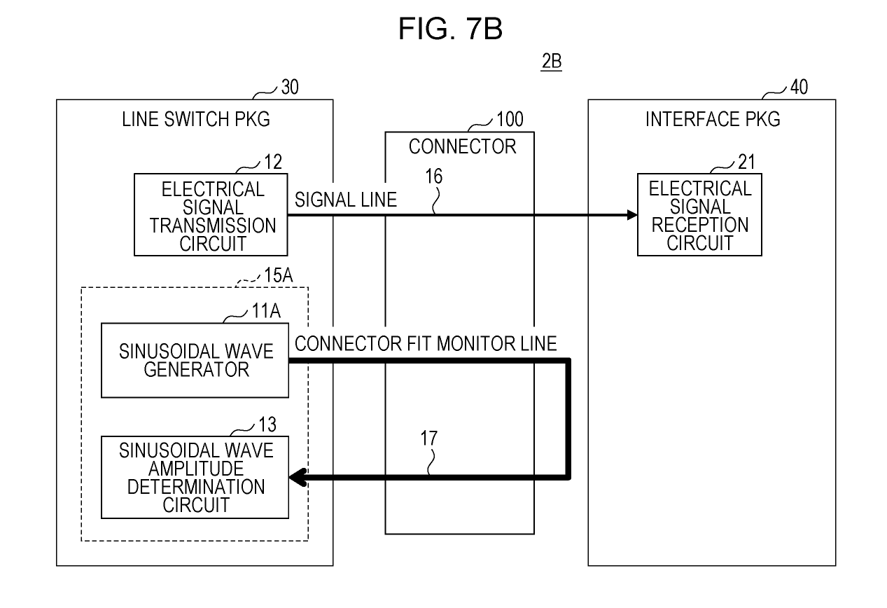

FIG. 7A is a schematic diagram of a transmission apparatus 2A to which the first embodiment is applied. In the transmission apparatus 2A, line switch blocks and line interface blocks are divided and packaged. A line switch package 30 and an interface package 40 are coupled to each other via the connector 100. An electrical signal generated and sent by the electrical signal transmission circuit 12 of the line switch package 30 is transmitted through the signal line 16 including the connection terminals of the connector 100, and is received by the electrical signal reception circuit 21 of the interface package 40.

A sine wave generation circuit 11A of a connection monitor 15A is disposed in the line switch package 30, and the sine wave amplitude determination circuit 13 is disposed in the interface package 40. The connector fit monitor line 17 extends from the line switch package 30 to the interface package 40 in one direction. This configuration is simple because the connector fit monitor line 17 does not have to loop around the connector 100 along the side surface thereof.

FIG. 7B is a schematic diagram of a transmission apparatus 2B. Like in FIG. 7A, line switch blocks and line interface blocks are divided and packaged. The connection monitor 15A having the sine wave generation circuit 11A and the sine wave amplitude determination circuit 13 is provided in the line switch package 30. The connector fit monitor line 17 loops around the connector 100 like in FIG. 4, extending along the side wall thereof and back to the line switch package 30. This configuration makes the connector fit monitor line 17 long, but allows the elements of the connection monitor 15A to be packaged into one.

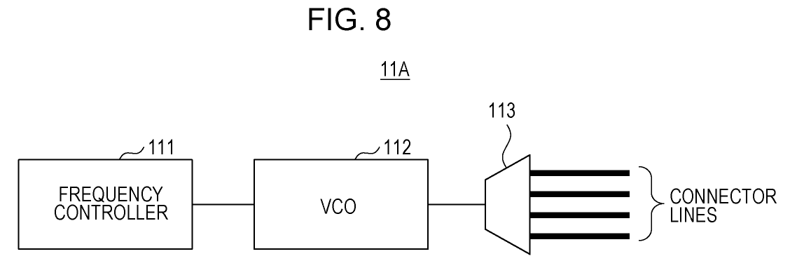

FIG. 8 is a schematic diagram of the sine wave generation circuit 11A used in FIGS. 7A and 7B. The sine wave generation circuit 11A has the frequency controller 111, the VCO 112, and a switch circuit 113 coupled to the output of the VCO 112. The frequency controller 111 and the VCO 112 have the same functionalities and configurations as those described with reference to FIG. 4. The switch circuit 113 may use part of a line switch circuit or function in the line switch package 30. The switch circuit 113 may test the inter-package fit state at the connector 100 by switching among a plurality of connector lines coupled to respective terminals of the connector 100. This configuration is advantageous in testing the fit state of a multipin connector.

### APPLICATION EXAMPLE 2

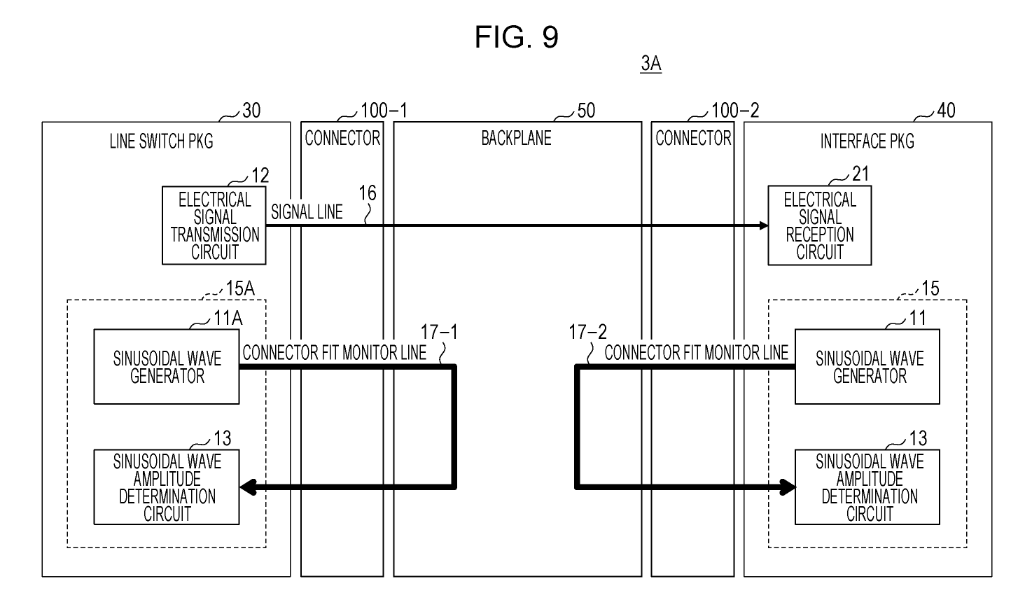

FIG. 9 is a schematic diagram of a transmission apparatus 3A. The transmission apparatus 3A is such that line switch blocks and line interface blocks are divided and packaged, and coupled to each other via a backplane 50. The line switch package 30 and the backplane 50 are coupled to each other with a connector 100-1, and the backplane 50 and the interface package 40 are coupled to each other with a connector 100-2. Each of the line switch package 30 and the interface package 40 has a connection monitoring configuration, each with an independent monitor line. The line switch package 30 has the connection monitor 15A, and uses a looped connector fit monitor line 17-1. The interface package 40 has the connection monitor 15, and uses a looped connector fit monitor line 17-2.

On the connector fit monitor line 17-1, a sine signal is outputted to the backplane 50 through the connector 100-1, and returns from the backplane 50 to the connection monitor 15A of the line switch package 30 through the connector 100-1. On the connector fit monitor line 17-2, a sine signal is outputted to the backplane 50 through the connector 100-2, and returns from the backplane 50 to the connection monitor 15 of the interface package 40. This configuration enables independent testing of a poor fit at the connector 100-1 and a poor fit at the connector 100-2, allowing speedy and accurate identification of the location of the poor fit.

The sine wave generation circuit 11A of the connection monitor 15A has the configuration in FIG. 8, and is able to test the fit state by switching among a plurality of lines using the line switch function or configuration in the line switch package 30. Use of the line switch configuration in the package is advantageous in testing a multipin connector, but is not requisite. Instead of the connection monitor 15A, the connection monitor 15 in FIG. 4 may be used. The sine wave generation circuit 11 of the connection monitor 15 in the interface package 40 has the configuration and functionality described with reference to FIG. 4, or alternatively, may have the same configuration as the connection monitor 15A by having a switch circuit incorporated therein.

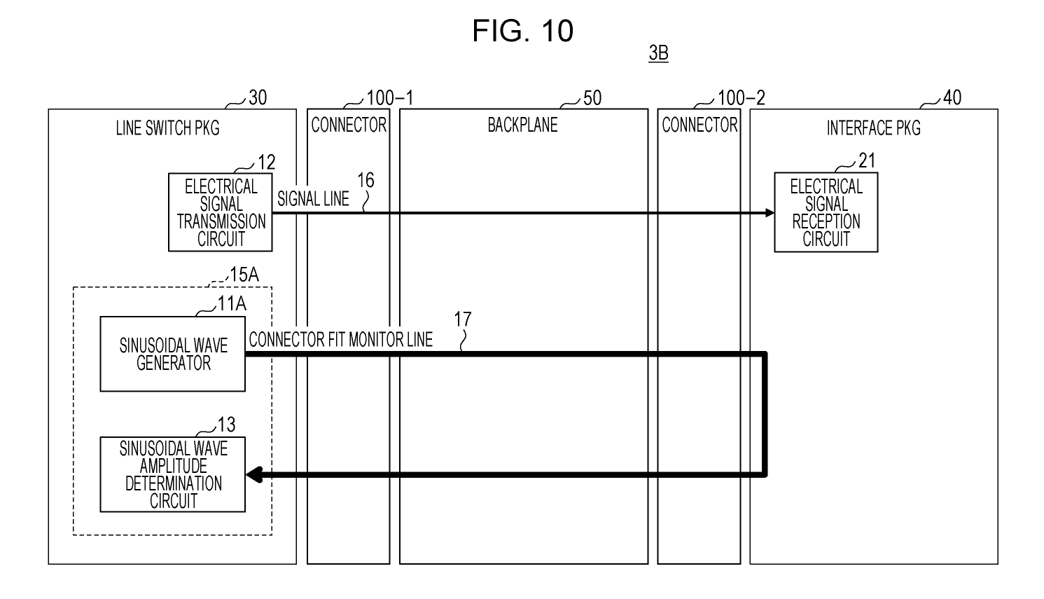

FIG. 10 is a schematic diagram of a transmission apparatus 3B which is another application example of the first embodiment. The transmission apparatus 3A is such that, like in FIG. 9, line switch blocks and line interface blocks are divided and packaged, and coupled to each other via the backplane 50. The line switch package 30 and the backplane 50 are coupled to each other with the connector 100-1, and the backplane 50 and the interface package 40 are coupled to each other with the connector 100-2.

The line switch package 30 has the connection monitor 15A. The connector fit monitor line 17 forms a loop passing through the connector 100-1, the backplane 50, and the connector 100-2. A sine signal is outputted to the interface package 40 through the connector 100-1, the backplane 50, and the connector 100-2, loops back to the line switch package 30, and is inputted to the connection monitor 15A. The sine wave generation circuit 11A of the connection monitor 15A has the configuration in FIG. 8, and is able to test the fit state for a plurality of lines. Instead of the sine wave generation circuit 11A, the sine wave generation circuit 11 in FIG. 4 may be used.

The configuration in FIG. 10 is simple in its arrangement since the connection monitor 15A is provided in only one of the packages, and the inter-package fit states of the two connectors are tested using one connector fit monitor line 17.

### APPLICATION EXAMPLE 3

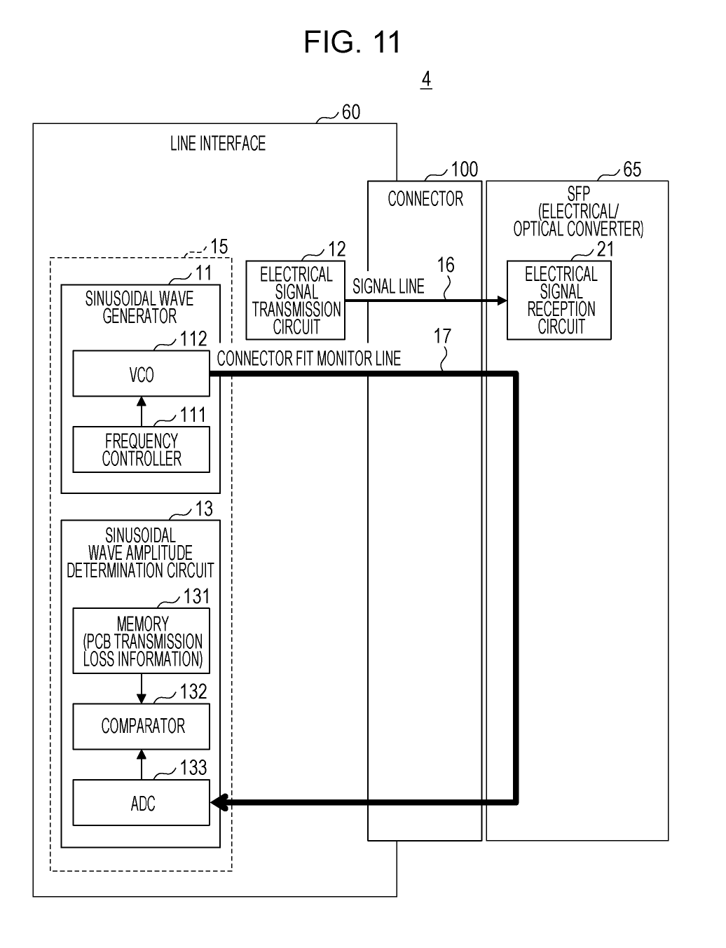

FIG. 11 is a schematic diagram illustrating a transmission apparatus 4, yet another application example of the first embodiment. In the transmission apparatus 4, a pluggable module, such as a small form-factor pluggable (SFP) 65, is coupled to another module, such as a line interface 60, via the connector 100. The SFP 65 is, for example, an electrical/optical conversion chip such as an LED array. An electrical signal outputted from the electrical signal transmission circuit 12 of the line interface 60 passes through the signal line 16 and is received by the electrical signal reception circuit 21 of the SFP 65.

The line interface 60 has the connection monitor 15, and tests the fit state of the connector 100 using the looped connector fit monitor line 17. The connection monitor 15 has the same configuration and functionality as the connection monitor 15 in FIG. 4. The sine wave generation circuit 11 generates and outputs a sine signal in a frequency band higher than the frequency of an electrical signal propagated through the signal line 16. The sine wave amplitude determination circuit 13 evaluates transmission degradation of the connector 100 based on degradation in the amplitude of the sine signal received through the connector fit monitor line 17.

This configuration enables determination of whether the connector 100 has a poor inter-module fit allowing signal continuity but affecting data transmission.

### APPLICATION EXAMPLE 4

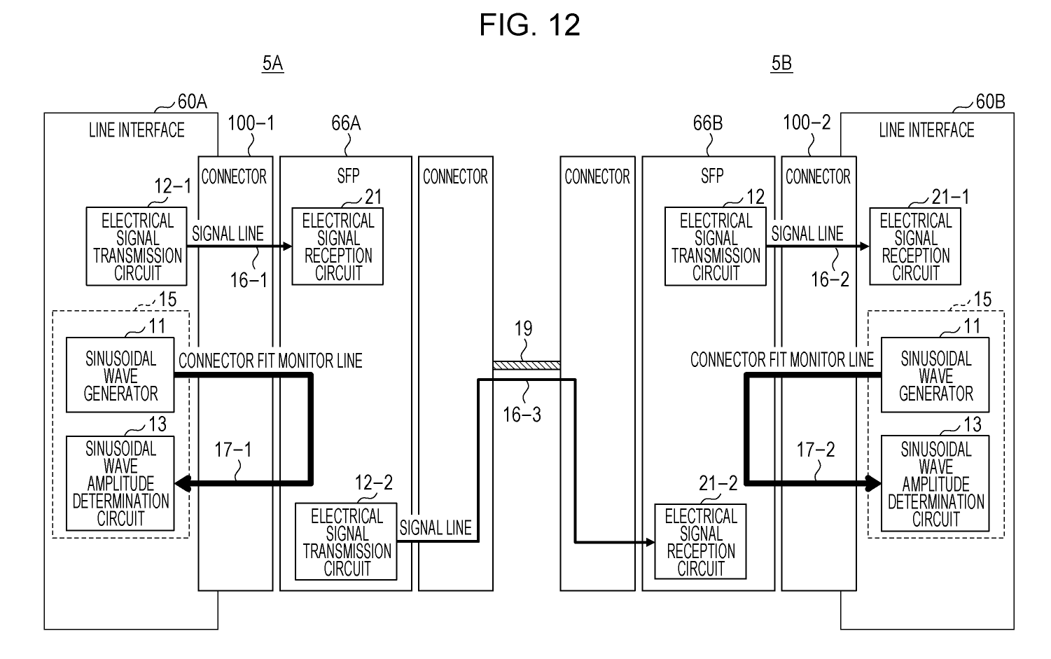

FIG. 12 is a schematic diagram of a transmission system 6, yet another application example of the first embodiment. In the transmission system 6, a transmission apparatus 5A and a transmission apparatus 5B are coupled to each other via a high-frequency cable 19 with a connector.

The transmission apparatus 5A is such that a pluggable module, such as an SFP 66A, is coupled to another module, such as a line interface 60A, via the connector 100-1. The SFP 66A is, for example, a copper transceiver module. An electrical signal outputted from an electrical signal transmission circuit 12-1 of the line interface 60A is received by the electrical signal reception circuit 21 of the SFP 66A through a signal line 16-1. The line interface 60A has the connection monitor 15, and tests the inter-module fit state at the connector 100-1 using the connector fit monitor line 17-1. The connection monitor 15 has the same configuration and functionality as the connection monitor 15 in FIG. 4.

An electrical signal outputted from an electrical signal transmission circuit 12-2 of the SFP 66A of the transmission apparatus 5A is transmitted to the transmission apparatus 5B through the high-frequency cable 19, and received by an electrical signal reception circuit 21-2 of the transmission apparatus 5B. A signal path that extends from the electrical signal transmission circuit 12-2 to the electrical signal reception circuit 21-2 through the high-frequency cable 19 is denoted as a signal line 16-3.

The transmission apparatus 5B is such that a pluggable module, such as a SFP 66B, is coupled to another module, such as a line interface 60B, via the connector 100-2. The SFP 66B is, for example, a copper transceiver module. An electrical signal outputted from the electrical signal transmission circuit 12 of the SFP 66B is received by the electrical signal reception circuit 21-2 of the line interface 60B through a signal line 16-2. The line interface 60B has the connection monitor 15, and tests the inter-module fit state at the connector 100-2 using the connector fit monitor line 17-2. The connection monitor 15 has the same configuration and functionality as the connection monitor 15 in FIG. 4.

This configuration enables the transmission apparatus 5A and the transmission apparatus 5B to test a poor fit at the connector 100-1 and a poor fit at the connector 100-2 independently. Since a transmission loss is tested for a frequency domain higher than the frequencies of signals propagated through the signal lines 16-1 and 16-2, the configuration is advantageously applicable to a high-speed telecommunications system that uses the high-frequency cable 19.

### APPLICATION EXAMPLE 5

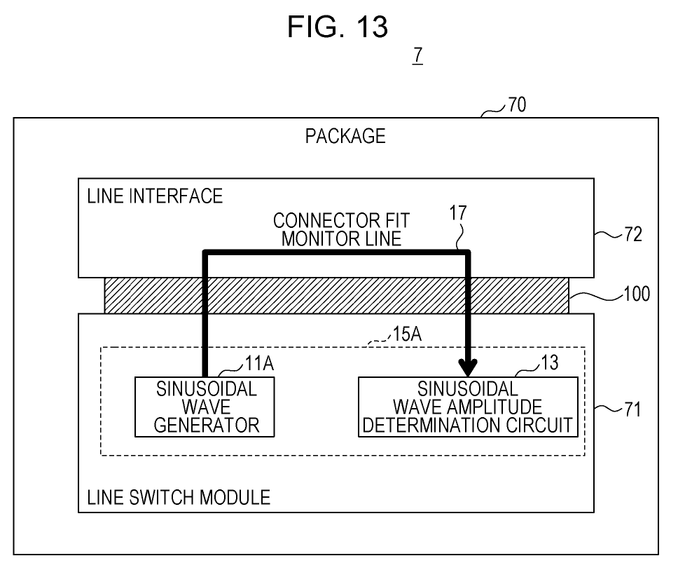

FIG. 13 is a schematic diagram of a transmission apparatus 7, yet another application example of the first embodiment. The transmission apparatus 7 has a packaged structure in which a line switch module 71 and a line interface 72 are stacked within a package 70 with the connector 100 interposed therebetween. The connector 100 is, for example, a ball grid array or a pin grid array having a plurality of terminals, and is used in high-density packaging. Between the line switch module 71 and the line interface 72, electrical signals are transmitted and received through an electrical signal line using the connector 100.

The line switch module 71 has the connection monitor 15A, and detects a poor fit at the connector 100 using a high-frequency sine signal and the connector fit monitor line 17. As an example, a sine signal is transmitted and received using the terminal at the outermost corner of the grid array, and based on degradation in the amplitude of the sine wave received, transmission degradation at the connector 100 is evaluated to determine whether the connector has a poor fit. When the connector 100 used has many terminals like a ball grid array or a pin grid array, it is desirable that the switching configuration of the line switch module 71 be used to carry out a test while switching among a plurality of terminals.

<Examples of how Connector Fit Monitor Line is Laid>

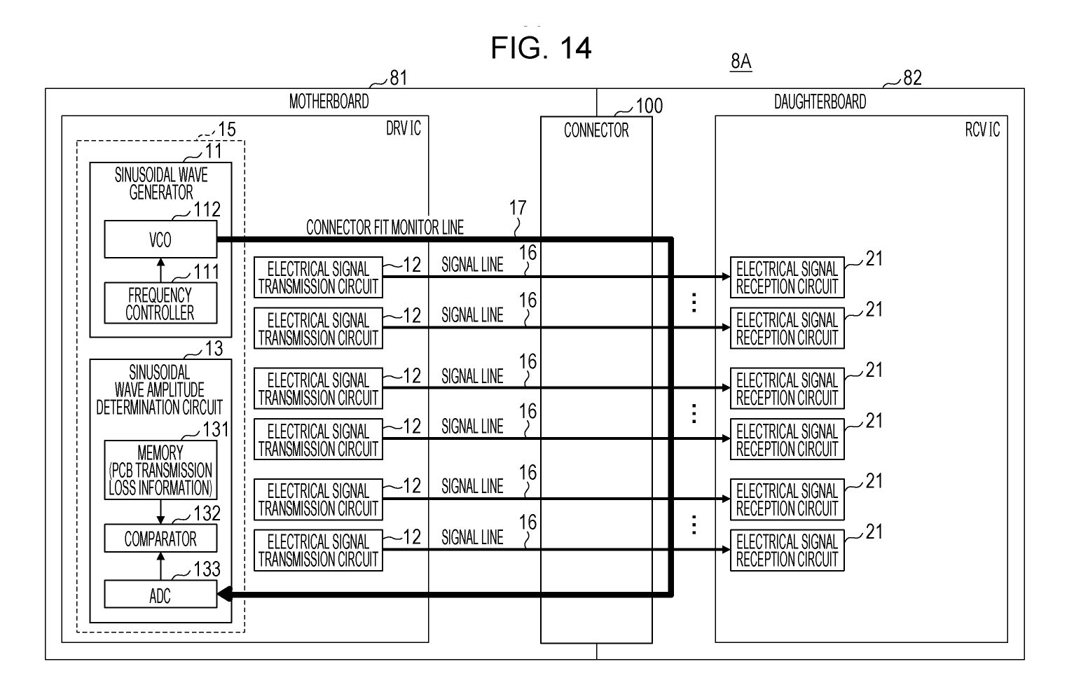

FIG. 14 is a diagram illustrating an example of how the connector fit monitor line 17 is laid. A transmission apparatus 8A in FIG. 14 is such that a daughterboard 82 is coupled to a motherboard 81 via the connector 100. The motherboard 81 includes a driver circuit (DRV IC) having a plurality of electrical signal transmission circuits 12. The daughterboard 82 includes a receiver circuit (RCV IC) having a plurality of electrical signal reception circuits 21. High-speed signals are delivered between the motherboard 81 and the daughterboard 82 through a plurality of signal lines 16. When a single connector fit monitor line 17 is used for poor fit monitoring on a configuration having high-speed electrical signals passing through a plurality of lines, it is preferable to lay the connector fit monitor line 17 along the side surface of the connector 100 on the sine signal output side. In the example in FIG. 14, the connector fit monitor line 17 is laid on the daughterboard 82 side in the direction of the terminal array of the connector 100. A sine signal is outputted from the motherboard 81 to the daughterboard 82 through an end portion of the connector 100, and is outputted from the daughterboard 82 to the motherboard 81 through the other end portion of the connector 100. This is because when the connector has a slanted fit, signal degradation appears prominently on a side surface of the connector 100.

This configuration enables appropriate detection of a poor fit which permits signal continuity, without increasing the number of the connection monitors 15 or the number of the connector fit monitor lines 17.

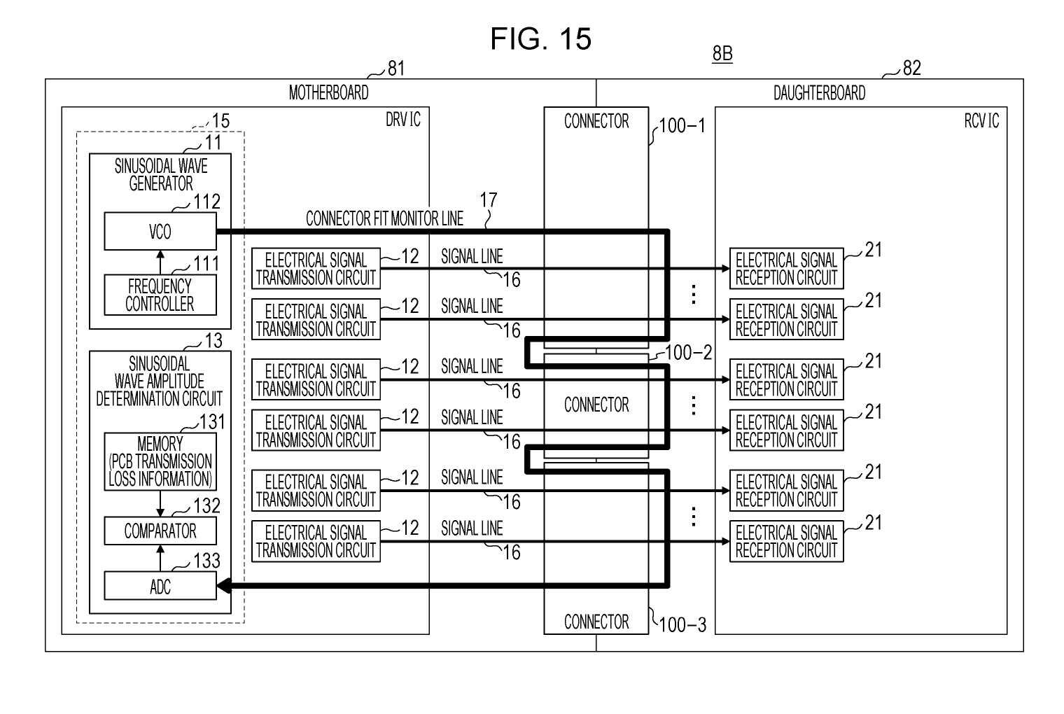

FIG. 15 illustrates an example of how the connector fit monitor line 17 is laid when the motherboard 81 and the daughterboard 82 are coupled to each other via a plurality of connectors 100-1, 100-2, and 100-3. The motherboard 81 includes a driver circuit (DRV IC) having a plurality of electrical signal transmission circuits 12. The daughterboard 82 includes a receiver circuit (RCV IC) having a plurality of electrical signal reception circuits 21. High-speed electrical signals are delivered between the motherboard 81 and the daughterboard 82 through a plurality of signal lines 16 passing through the connectors 100-1, 100-2, and 100-3.

The connector fit monitor line 17 is coupled in a daisy chain pattern through the side surfaces of the connectors 100-1, 100-2, and 100-3. This configuration enables appropriate detection of a poor fit which permits signal continuity, without increasing the number of the connection monitors 15 or the number of the connector fit monitor lines 17 even when a plurality of connectors 100-1, 100-2, and 100-3 are used for inter-board connection.

<Modifications>

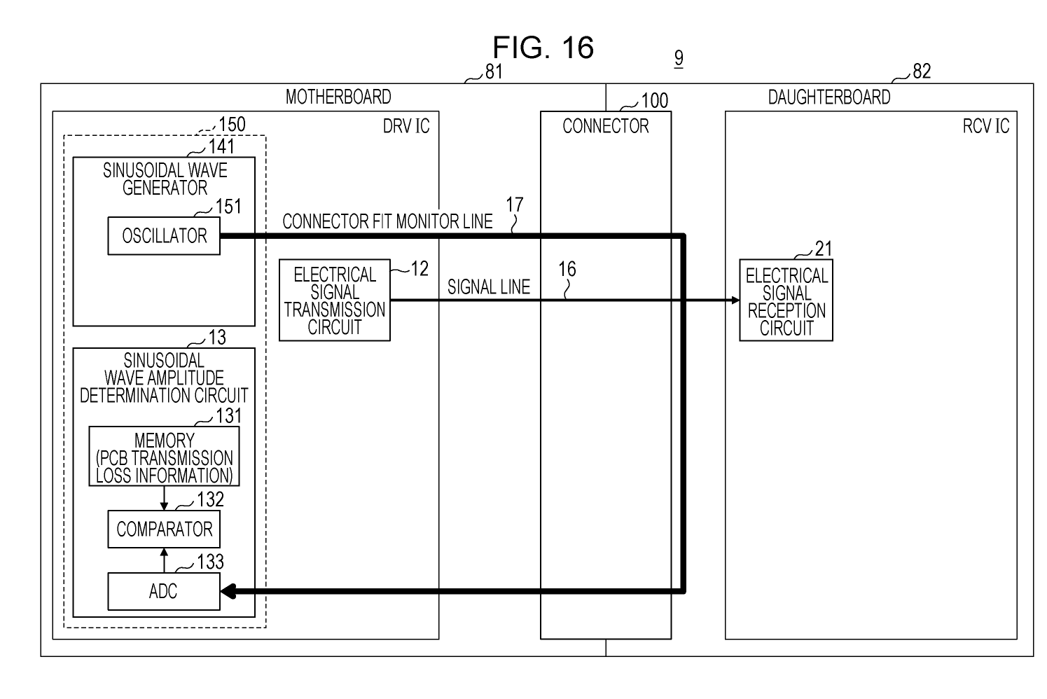

FIG. 16 illustrates a modification of a sine wave generation circuit. In this modification, a sine wave at a single frequency is generated and outputted. A transmission apparatus 9 has the motherboard 81 and the daughterboard 82 coupled to each other with the connector 100. Through the signal line 16, an electrical signal is transmitted from the electrical signal transmission circuit 12 of the motherboard 81 to the electrical signal reception circuit 21 of the daughterboard 82.

The motherboard 81 has a connection monitor 150. The connection monitor 150 has a sine generation circuit 141, the sine wave amplitude determination circuit 13, and the connector fit monitor line 17 extending through the connector 100 and connecting the sine generation circuit 141 and the sine wave amplitude determination circuit 13 to each other.

An oscillator 151 in the sine generation circuit 141 generates and outputs a sine wave. When the stub length L caused inside the connector 100 is known, the inter-board fit state at the connector 100 may be tested using a frequency at which the stub is most influential. For example, as described with reference to FIG. 2, signal degradation becomes prominent in a frequency range where the stub length L approximates to λ/4, where λ is the wavelength used. With electrical signals becoming higher in speed (shorter in wavelength) in recent years, even a small stub in the connector fit part is not negligible. When the stub length at the connector fit part is 4 mm, stub reflection is most influential when the wavelength λ is 16 mm, or in other words, when the frequency is 18.7 GHz. In this case, the oscillating frequency for the oscillator 151 is set to 18.7 GHz. The frequency of an electrical signal actually transmitted and received may be lower than the oscillating frequency of the oscillator 151, and may be, for example, a signal of 10 GHz.

The sine wave amplitude determination circuit 13 determines that the connector 100 has a poor fit when the amplitude of the sine wave received has been degraded, and the calculated amount of the degradation exceeds a tolerable transmission loss. A poor fit under the environment of high-speed telecommunications is thus detectable appropriately.

The present disclosure has been described above based on particular embodiments, but is not limited to these embodiments. Two or more configuration examples may be combined if appropriate, or the sine wave generation circuit 11A with a line switch function may be used in a module without a line switching function. When the structure of a connector that couples boards or cards together is known, a sine wave having a fixed frequency at which the stub is most influential may be used instead of sweeping the frequency of a sine wave like in the connection monitoring process in FIG. 6.

A terminal in the connector does not have to be a multicontact terminal, and may be a terminal having such a shape that may unstably connect to the corresponding terminal depending on the angle of insertion. For example, in a stack structure like the one illustrated in FIG. 13, when the via stub length for a signal via in the module coupled to the connector 100 is ¼ of the signal wavelength, signal transmission becomes unstable because the signals cancel each other out due to stub reflection. Also in this case, a high-frequency wave at which a stub is most influential may be used to test whether the connector has a proper fit. As the sine generation circuit, any signal generation circuit capable of generating an AC signal at a frequency higher than the transmission rate for a data signal is usable.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A transmission apparatus comprising a first circuit, a second circuit, and a connector that couples the first circuit and the second circuit to each other, wherein
the first circuit has a signal generation circuit that outputs an alternate current signal of a predetermined power at a frequency from a carrier frequency to three times the carrier frequency, and
one of the first circuit and the second circuit has a determination circuit that evaluates a fit state at the connector by determining whether the first circuit and the second circuit are fitted to each other via the connector based on the predetermined power and a power of the alternate current signal received by the determination circuit via the connector.

2. The transmission apparatus according to claim 1, wherein
the signal generation circuit outputs alternate current signals of predetermined powers at various frequencies in a frequency higher than the carrier frequency, and
the determination circuit evaluates the fit state at the connector based on the predetermined powers and powers of the alternate current signals at the various frequencies received by the determination circuit via the connector.

3. The transmission apparatus according to claim 2, wherein the frequency includes a harmonic of the carrier frequency.

4. The transmission apparatus according to claim 1, wherein
the signal generation circuit outputs an alternate current signal at a frequency which is higher than the carrier frequency and corresponds to a wavelength which is four times a length of a stub in the connector, and
the determination circuit evaluates the fit state at the connector based on a power level of the alternate current signal at the frequency.

5. The transmission apparatus according to claim 4, wherein the stub is a stub caused in an internal terminal of the connector, or a stub caused in a signal via inside the first circuit or the second circuit.

6. The transmission apparatus according to claim 1, wherein
the signal generation circuit and the determination circuit are disposed in the first circuit, and
the alternate current signal is outputted to the second circuit via the connector, and looped back from the second circuit to the first circuit via the connector.

7. The transmission apparatus according to claim 1, wherein
the signal generation circuit is disposed in the first circuit,
the determination circuit is disposed in the second circuit,
the alternate current signal is outputted to the second circuit via the connector, and
the fit state at the connector is evaluated in the second circuit.

8. The transmission apparatus according to claim 1, comprising a monitor line that couples an output of the signal generation circuit to an input of the determination circuit via the connector, wherein
the first circuit and the second circuit are coupled to each other with a plurality of connectors, and
the monitor line passes via the plurality of connectors in a daisy chain pattern.

9. The transmission apparatus according to claim 1, comprising a monitor line that couples an output of the signal generation circuit to an input of the determination circuit via the connector, wherein
data is transmitted on a plurality of signal lines via the connector, and
the monitor line is laid along a side wall of the connector in a terminal array direction.

10. The transmission apparatus according to claim 1, wherein the determination circuit outputs a warning when a decrease in the power of the alternate current signal received exceeds a tolerable transmission loss of the transmission apparatus.

11. The transmission apparatus according to claim 10, further comprising a memory that stores information indicating a relation between a frequency and a transmission loss of the transmission apparatus, wherein
by referring to the memory, the determination circuit determines whether the fit state at the connector is proper.

12. A transmission system comprising a first circuit, a second circuit, and a cable with a connector that couples the first circuit and the second circuit to each other, wherein
the first circuit has a signal generation circuit that outputs an alternate current signal of a predetermined power at a frequency from a carrier frequency to three times the carrier frequency, and
one of the first circuit and the second circuit has a determination circuit that evaluates a fit state at the connector by determining whether the first circuit and the second circuit are fitted to each other via the connector based on the predetermined power and a power of the alternate current signal received by the determination circuit via the connector.

13. A connection monitoring method in a transmission apparatus comprising a first circuit, a second circuit, and a connector that couples the first circuit and the second circuit to each other, the method comprising:
outputting, by a signal generation circuit in the first circuit, an alternate current signal of a predetermined power at a frequency from a carrier frequency to three times the carrier frequency, to a second circuit via the connector,
receiving, by a determination circuit, the alternate current signal via the connector,
determining whether the first circuit and the second circuit are fitted to each other via the connector based on the predetermined power and a power of the alternate current signal received by the determination circuit via the connector, and
evaluating a fit state at the connector.

14. The connection monitoring method according to claim 13, wherein the frequency includes a harmonic of the carrier frequency.

15. The connection monitoring method according to claim 13, wherein the determination circuit outputs a warning when a decrease in the power of the alternate current signal received exceeds a tolerable transmission loss of the transmission apparatus.
